(19) United States
(12) Patent Application Publication
(10) Pub. No.: US 2026/0122802 A1
(43) Pub. Date: Apr. 30, 2026

(54) DISPLAY MODULE AND DISPLAY DEVICE

(71) Applicant: Shanghai Tianma Microelectronics Co., Ltd., Shanghai (CN)

(72) Inventor: Shouzheng Wu, Shanghai (CN)

(73) Assignee: Shanghai Tianma Microelectronics Co., Ltd., Shanghai (CN)

(21) Appl. No.: 19/433,436

(22) Filed: Dec. 26, 2025

(30) Foreign Application Priority Data
Jul. 31, 2025 (CN) 202511076074.8

(51) Int. Cl. H05K 5/02

(52) U.S. Cl. CPC H05K 5/0217

(57) ABSTRACT

Provided are a display module and a display device. The display module comprises a bracket structure, an adhesion-reducing adhesive structure, a plurality of display panels and a plurality of back plates. The back plate is disposed on a non-light-emission side of the display panel. The bracket structure is disposed on a side of the back plate away from the display panel through the adhesion-reducing adhesive structure, and the adhesion of the adhesion-reducing adhesive structure is variable.

### CROSS-REFERENCE TO RELATED APPLICATIONS

This application claims priority to Chinese Patent Application No. 202511076074.8 filed July 31, 2025, the disclosure of which is incorporated herein by reference in its entirety.

### TECHNICAL FIELD

The present disclosure relates to the field of display, and in particular to a display module and a display device.

### BACKGROUND

When a tiled display panel in the related art is spliced, traditional detachable structures such as buckles or quick-release screws are typically used to achieve detachable splicing of the tiled display panel. However, the traditional detachable structures require a large space at the splicing gap to be left to accommodate part of the disassembled structure, resulting in a splicing gap of hundreds of microns. The splicing gap is large and cannot satisfy high-quality and high-specification product requirements.

### SUMMARY

The embodiments of the disclosure provide a display module and a display device. A bracket structure is fixed with a back plate through an adhesion-reducing adhesive structure. When disassembly is required, a specific condition is applied to the adhesion-reducing adhesive structure so that the adhesion of the adhesion-reducing adhesive structure can be reduced and the bracket structure can be disassembled from the back plate, achieving the detachable fixation between the back plate and the bracket structure. Moreover, the traditional detachable structure is not required to be disposed between the splicing gap of the display panel, the splicing gap can be reduced, and the operation is simple and convenient.

In a first aspect, an embodiment of the present disclosure provides a display module. The display module includes a bracket structure, an adhesion-reducing adhesive structure, multiple display panels, and multiple back plates.

The back plates are disposed on a non-light-emission side of the display panel.

The bracket structure is disposed on a side of the back plates facing away from the display panel through the adhesion-reducing adhesive structure, and the adhesion of the adhesion-reducing adhesive structure is variable.

In a second aspect, an embodiment of the present disclosure further provides a display device including the display panel in the first aspect.

### BRIEF DESCRIPTION OF DRAWINGS

FIG. 1 is a schematic sectional view of a display module provided by an embodiment of the present disclosure.

FIG. 2 is a schematic sectional view of another display module provided by an embodiment of the present disclosure.

FIG. 3 is a schematic sectional view of another display module provided by an embodiment of the present disclosure.

FIG. 4 is a schematic sectional view of another display module provided by an embodiment of the present disclosure.

FIG. 5 is a schematic sectional view of another display module provided by an embodiment of the present disclosure.

FIG. 6 is a schematic sectional view of another display module provided by an embodiment of the present disclosure.

FIG. 7 is a partial structural diagram of an electrode structure provided by an embodiment of the present disclosure.

FIG. 8 is a partial structural diagram of another electrode structure provided by an embodiment of the present disclosure.

FIG. 9 is a partial structural diagram of another electrode structure provided by an embodiment of the present disclosure.

FIG. 10 is a partial structural diagram of another electrode structure provided by an embodiment of the present disclosure.

FIG. 11 is a structural schematic diagram of a display module provided by an embodiment of the present disclosure.

FIG. 12 is a schematic sectional view along the direction AA' in FIG. 11.

FIG. 13 is a structural schematic diagram of another display module provided by an embodiment of the present disclosure.

FIG. 14 is a structural schematic diagram of another display module provided by an embodiment of the present disclosure.

FIG. 15 is a structural schematic diagram of another display module provided by an embodiment of the present disclosure.

FIG. 16 is a structural schematic diagram of another display module provided by an embodiment of the present disclosure.

FIG. 17 is a structural schematic diagram of another display module provided by an embodiment of the present disclosure.

FIG. 18 is a structural schematic diagram of another display module provided by an embodiment of the present disclosure.

FIG. 19 is a structural schematic diagram of another display module provided by an embodiment of the present disclosure.

FIG. 20 is a functional schematic diagram of a driver chip provided by an embodiment of the present disclosure.

FIG. 21 is a schematic sectional view of another display module provided by an embodiment of the present disclosure.

FIG. 22 is a structural schematic diagram of a display device provided by an embodiment of the present disclosure.

FIG. 23 is a structural schematic diagram of another display device provided by an embodiment of the present disclosure.

### DETAILED DESCRIPTION

To illustrate the purpose, technical solution and advantages of the present disclosure more clearly, the solutions of the present disclosure are described completely hereinafter through embodiments in conjunction with the drawings in the embodiments of the present disclosure. Apparently, the embodiments described herein are only part of the embodiments of the present disclosure, but not all of the embodiments, and based on the embodiments of the present application, all other embodiments obtained by those of ordinary skill in the art on the premise that no creative work is done fall within the scope of the present application.

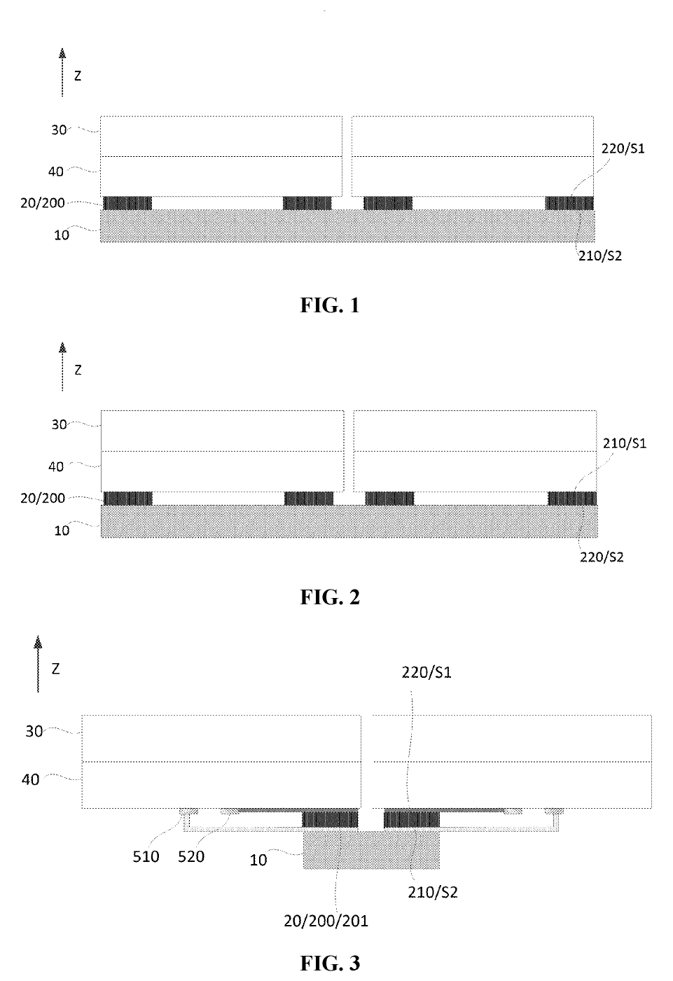

FIG. 1 is a schematic sectional view of a display module provided by an embodiment of the present disclosure. Referring to FIG. 1, the display module includes a bracket structure 10, an adhesion-reducing adhesive structure 20, multiple display panels 30 and multiple back plates 40. The multiple back plates 40 are disposed on the non-light-emission side of the display panel 30. The bracket structure 10 is disposed on the side of the back plate 40 facing away from the display panel 30 through the adhesion-reducing adhesive structure 20, and the adhesion of the adhesion-reducing adhesive structure 20 is variable.

Exemplarily, as shown in FIG. 1, the display module includes multiple display panels 30. Exemplarily, two display panels 30 are taken as an example in FIG. 1, but the present disclosure is not limited to this. In other embodiments, the display module may also include display panels 30 with another number. Specifically, the display panel 30 includes a light-emission surface and a non-light-emission surface, and the light-emission surface and the non-light-emission surface are disposed opposite to each other. The light-emission surface may include a display area (not shown in the figure). For example, when the display panel includes an organic light-emitting diode (OLED) display panel or a micro-LED display panel, the display area includes multiple light-emitting elements disposed in an array, and image display can be realized through the light emission of the multiple light-emitting elements. When the display panel includes a liquid crystal display (LCD) panel, the display area includes a liquid crystal layer and a color filter substrate located at the side of the liquid crystal layer facing away from the substrate. The light-transmissive state of the liquid crystal layer is controlled by controlling a deflection state of liquid crystal molecules in the liquid crystal layer, and the color display of the image is realized through color resistance blocks in the color filter substrate. When the display panel includes an electronic paper, the display area includes an electrophoretic layer, and the electrophoretic layer implements image display by reflecting light. The non-light-emission surface may support a device and a driving device. For example, the non-light-emission surface may also be provided with multiple back plates 40, and the back plates 40 may be disposed in one-to-one correspondence with the display panels 30 to support the display panels 30 through the respective back plates 40. Furthermore, a driver chip (not shown in the figure) may be disposed on the side of the back plate 40 facing away from the display panel 30, and a light emission control signal for the display area may be provided by the driver chip.

With continued reference to FIG. 1, the display module further includes at least one bracket structure 10. Along the thickness direction Z of the display panel 30, the bracket structure 10 at least partially overlaps at least two display panels 30. In other words, along the thickness direction Z of the display panel 30, the bracket structure 10 at least partially overlaps a splicing gap of two adjacent display panels 30; thus, the two display panels 30 tiled together are supported by the bracket structure 10. Moreover, the bracket structure 10 may be a metal bracket structure, which can conduct and release the static electricity on the display panels 30 while supporting the two display panels 30 tiled together. For a tiled display panel, when the overall device is abnormal, the display panels are typically required to be disassembled separately, so that the targeted maintenance can be achieved and maintenance costs can be reduced. In the prior art, traditional detachable structures such as buckles or quick-release screws are disposed in the splicing gap of the tiled display panel to realize the detachable splicing of the tiled display panels. However, the traditional detachable structures require a mechanical means for disassembly, and the mechanical means is difficult and prone to damaging the display panels. Furthermore, the traditional detachable structure is disposed at the splicing gap between two adjacent display panels, while the volume of buckles or quick-release screws is large, resulting in a larger splicing gap between two adjacent display panels and failing to satisfy the application requirements.

In this regard, the embodiments of the present disclosure further define the display module to include an adhesion-reducing adhesive structure 20. The bracket structure 10 and the back plates 40 are fixed by the adhesion-reducing adhesive structure 20. The characteristic of the adhesion-reducing adhesive structure 20 is that the adhesion is variable under a specific condition. Exemplarily, under a normal condition, the adhesion of the adhesion-reducing adhesive structure 20 is relatively high, and the bracket structure 10 is fixed on the side of the back plates 40 facing away from the display panels 30. Along the thickness direction Z of the display panel 30, the bracket structure 10 at least partially overlaps the splicing gap between two adjacent display panels 30, so that the bracket structure 10 supports the splicing gap between two adjacent display panels 30 to ensure the tiled stability of the display module. Moreover, when the display panel 30 needs to be disassembled since the display module is abnormal or the test is performed on the display module, the specific condition may be provided for the adhesion-reducing adhesive structure 20 of the display module. It can be understood that when the display panel is disassembled, the specific condition may be provided for all the adhesion-reducing adhesive structures 20 of the display module, or the specific condition may be provided for the adhesion-reducing adhesive structure 20 corresponding to a certain display panel 30, the embodiments of the present disclosure are not limited to this, and those skilled in the art may configure it as needed. Under the specific condition, the adhesion of the adhesion-reducing adhesive structure 20 is reduced so that the bracket structure 10 can be conveniently separated from the back plates 40. After all the adhesion-reducing adhesive structures 20 corresponding to the back plates 40 are separated from the back plates 40, the back plates 40 and the display panels 30 corresponding to the back plates 40 can be disassembled from the bracket structure 10, so that the detachable fixation between the back plates 40 and the bracket structure 10, and the disassembly manner is simple and convenient. Moreover, since the adhesion-reducing adhesive structure 20 is disposed between the back plates 40 and the bracket structure 10 without occupying the space of the splicing gap between two adjacent display panels 30, the spacing of the splicing gap between two adjacent display panels 30 can be reduced, thereby improving the tiled effect.

It should be noted that, in an embodiment, the specific condition may be applying light, the characteristic of the adhesion-reducing adhesive structure 20 is that the adhesion is reduced under the light exposure. The light is applied to the adhesion-reducing adhesive structure 20 so that the bracket structure 10 is separated from the back plates 40. In another embodiment, the specific condition may also be applying a voltage, and the characteristic of the adhesion-reducing adhesive structure 20 is that the adhesion is reduced under the action of an electric field. The electric field is applied to the adhesion-reducing adhesive structure 20 so that the bracket structure 10 is separated from the back plates 40. In another embodiment, the specific condition may also be applying a set temperature, and the characteristic of the adhesion-reducing adhesive structure 20 is that the adhesion is reduced at the set temperature. The specific temperature is applied to the adhesion-reducing adhesive structure 20 so that the bracket structure 10 is separated from the back plates 40, etc. The embodiments of the present disclosure do not limit the specific condition and the type of the adhesion-reducing adhesive structure 20, and those skilled in the art may configure it as needed.

In summary, according to the embodiments of the disclosure, the adhesion-reducing adhesive structure is disposed between the bracket structure and the back plates, and the characteristic of the adhesion-reducing adhesive structure is that the adhesion is variable. In this manner, under the normal condition, the adhesion-reducing adhesive structure has a relatively high adhesion, so that the bracket structure is fixed on the side of the back plate away from the display panel to support the tiled display panel. When disassembly is required, the adhesion of the adhesion-reducing adhesive structure is reduced by applying the specific condition to the adhesion-reducing adhesive structure, so that the bracket structure can be conveniently separated from the back plates and the detachable fixation of the back plates and the bracket structure can be realized. Moreover, since the detachable structure is disposed between the back plates and the bracket structure without occupying the space of the joint between two adjacent display panels, the spacing of the splicing gap between two adjacent display panels can be reduced, thereby improving the tiled effect.

In one or more embodiments, based on the above embodiment, with continued reference to FIG. 1, the adhesion-reducing adhesive structure 20 includes an electrical adhesion-reducing adhesive structure 200, and the specific condition includes applying a voltage. In this manner, under the normal condition, the electrical adhesion-reducing adhesive structure 200 has a relatively high adhesion so that the bracket structure can be fixed on the side of the back plates facing away from the display panels to support the tiled display panels. When disassembly is required, the voltage is applied to the electrical adhesion-reducing adhesive structure 200, and under the action of the electric field provided by the voltage, a force is generated between the electrical adhesion-reducing adhesive structure 200 and the back plates 40 or between the electrical adhesion-reducing adhesive structure 200 and the bracket structure 10, causing the change of the adhesive performance of the electrical adhesion-reducing adhesive structure 200; in other words, the adhesion of the electrical adhesion-reducing adhesive structure 200 is reduced, so that the electrical adhesion-reducing adhesive structure 200 can be easily separated from the back plates 40 or from the bracket structure 10, thereby achieving the detachable fixation between the back plates and the bracket structure. It should be noted that in the embodiments of the present disclosure, the adhesion-reducing adhesive structure 20 is merely exemplarily described as the electrical adhesion-reducing adhesive structure 200, but it is not limited to this, and will not be repeated here.

In one or more embodiments, based on the above embodiments, with reference to FIG. 1, the electrical adhesion-reducing adhesive structure 200 includes an adhesion-reducing surface 210 and a non-adhesion-reducing surface 220 disposed opposite to each other, and the adhesion of the adhesion-reducing surface 210 is variable.

Under the normal condition, the adhesion of the adhesion-reducing surface 210 is relatively high. When the voltage is applied to the adhesion-reducing surface 210, the adhesion of the adhesion-reducing surface 210 is reduced under the action of the electric field provided by the voltage, while the adhesion of the non-adhesion-reducing surface 220 remains unchanged under the normal condition and the action of the electric field provided by the voltage. Exemplarily, in the implementation shown in FIG. 1, the electrical adhesion-reducing adhesive structure 200 includes a first side S1 on the side of the electrical adhesion-reducing adhesive structure 200 facing the back plate 40 and a second side S2 on the side of the electrical adhesion-reducing adhesive structure 200 facing the bracket structure 10. The first side S1 is the non-adhesion-reducing surface 220, and the second side S2 is the adhesion-reducing surface 210. Thus, when the voltage is applied to the electrical adhesion-reducing adhesive structure 200, the adhesion of the adhesion-reducing surface 210 is reduced under the action of the electric field so that the adhesion between the second side S2 of the electrical adhesion-reducing adhesive structure 200 and the bracket structure 10 can be reduced, and the second side S2 is easily separated from the bracket structure 10. The adhesion of the non-adhesion-reducing surface 220 remains unchanged and still relatively high1 so that the adhesion between the first side S1 of the electrical adhesion-reducing adhesive structure 200 and the back plate 40 is relatively high, the first side S1 of the electrical adhesion-reducing adhesive structure 200 and the back plate 40 remains fixed, and the electrical adhesion-reducing adhesive structure 200 is separated from the bracket structure 10; in other words, the detachable fixation between the the back plate 40 and the bracket structure 10 is realized.

In another embodiment, FIG. 2 is a schematic sectional view of another display module provided by an embodiment of the present disclosure. Referring to FIG. 2, the electrical adhesion-reducing adhesive structure 200 includes a first side S1 on the side of the electrical adhesion-reducing adhesive structure 200 facing the back plate 40 and a second side S2 on the side of the electrical adhesion-reducing adhesive structure 200 facing the bracket structure 10. The first side S1 is the adhesion-reducing surface 210, and the second side S2 is the non-adhesion-reducing surface 220. Thus, when the voltage is applied to the electrical adhesion-reducing adhesive structure 200, the adhesion of the adhesion-reducing surface 210 is reduced under the action of the electric field so that the adhesion between the first side S1 of the electrical adhesion-reducing adhesive structure 200 and the back plate 40 can be reduced, and the first side S1 and the back plate 40 are easily separated. The adhesion of the non-adhesion-reducing surface 220 remains unchanged and still relatively high so that the adhesion between the second side S2 of the electrical adhesion-reducing adhesive structure 200 and the bracket structure 10 is relatively high, the second side S2 of the electrical adhesion-reducing adhesive structure 200 and the bracket structure 10 remains fixed, and the electrical adhesion-reducing adhesive structure 200 is separated from the back plate 40; in other words, the detachable fixation of the back plate 40 and the bracket structure 10 is realized.

In one or more embodiments, FIG. 3 is a schematic sectional view of another display module provided by an embodiment of the present disclosure. Referring to FIG. 3, the electrical adhesion-reducing adhesive structure 200 includes a first polarity adhesion-reducing adhesive structure 201. The display module further includes a first polarity signal output structure 510 and a second polarity signal output structure 520. The first polarity signal output structure 510 is configured to provide an electrical signal with a first polarity for the adhesion-reducing surface 210, and the second polarity signal output structure 520 is configured to provide an electrical signal with a second polarity for the non-adhesion-reducing surface 220. The first polarity is opposite to the second polarity.

Specifically, the first polarity adhesion-reducing adhesive structure 201 may be a positive electrical adhesion-reducing adhesive structure. The characteristic of the positive electrical adhesion-reducing adhesive structure is that the surface in contact with the positive electrical signal is the adhesion-reducing surface 210 and the surface in contact with the negative electrical signal is the non-adhesion-reducing surface 220. The display module further includes a first polarity signal output structure 510 and a second polarity signal output structure 520. The first polarity signal output structure 510 is configured to output an electrical signal with a first polarity, and the second polarity signal output structure 520 is configured to output an electrical signal with a second polarity. The first polarity may be the positive polarity, and the second polarity may be the negative polarity. As shown in FIG. 3, the first polarity signal output structure 510 is set to provide the electrical signal with the positive polarity to the second side S2 of the positive electrical adhesion-reducing adhesive structure to make the second side S2 as the adhesion-reducing surface 210, while the second polarity signal output structure 520 is configured to provide the electrical signal with the negative polarity to the first side S1 of the positive electrical adhesion-reducing adhesive structure to make the first side S1 as the non-adhesion-reducing surface 220. In this manner, the second side S2 of the positive electrical adhesion-reducing adhesive structure is separated from the bracket structure 10 when the electrical signal with the positive polarity is provided to the positive electrical adhesion-reducing adhesive structure. It can be understood that in the implementation shown in FIG. 3, the first polarity signal output structure 510 providing the electrical signal with the positive polarity for the second side S2 of the positive electrical adhesion-reducing adhesive structure is merely exemplary, but it is not limited to this. In other embodiments, the first polarity signal output structure 510 may also be configured to provide the electrical signal with the positive polarity to the first side S1 of the positive electrical adhesion-reducing adhesive structure to make the first side S1 the adhesion-reducing surface 210. At the same time, the second polarity signal output structure 520 is configured to provide the electrical signal with the negative polarity to the second side S2 of the positive electrical adhesion-reducing adhesive structure to make the second side S2 the non-adhesion-reducing surface 220. In this manner, the first side S1 of the positive electrical adhesion-reducing adhesive structure is separated from the back plate 40 when the electrical signal with the positive polarity is provided to the positive electrical adhesion-reducing adhesive structure.

It should be noted that when the first polarity signal output structure 510 is configured to provide the electrical signal with the positive polarity to the first side S1 of the positive electrical adhesion-reducing adhesive structure, the bracket structure 10 may also be configured to be grounded and in direct contact with the second side S2 of the positive electrical adhesion-reducing adhesive structure; in this manner, the electrical signal with the negative polarity is provided to the second side S2 of the positive electrical adhesion-reducing adhesive structure by the bracket structure 10 so that the manner of providing the electrical signal to the positive electrical adhesion-reducing adhesive structure is simple.

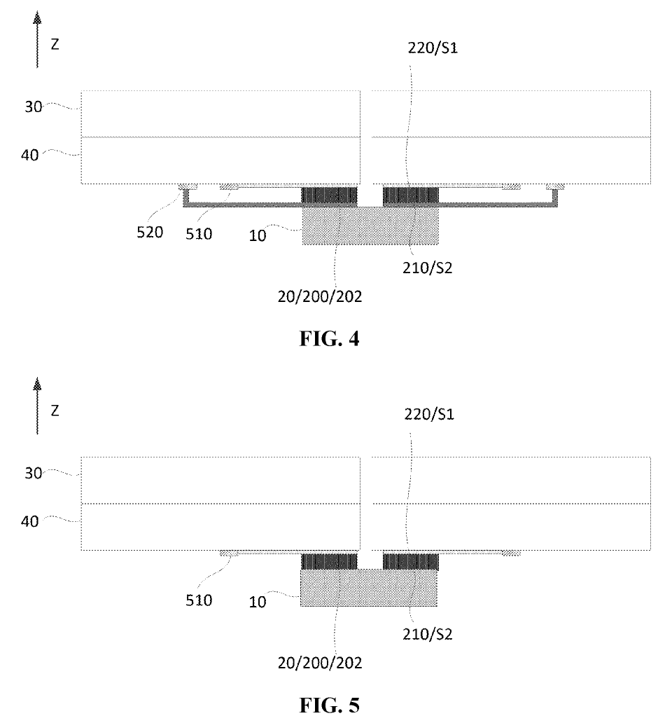

In one or more embodiments, FIG. 4 is a schematic sectional view of another display module provided by an embodiment of the present disclosure. Referring to FIG. 4, the electrical adhesion-reducing adhesive structure 200 may further include a second polarity adhesion-reducing adhesive structure 202. The second polarity adhesion-reducing adhesive structure 202 may be a negative electrical adhesion-reducing adhesive structure. The characteristic of the negative electrical adhesion-reducing adhesive structure is that the surface in contact with the negative electrical signal is the adhesion-reducing surface 210 and the surface in contact with the positive electrical signal is the non-adhesion-reducing surface 220. As shown in FIG. 4, the first polarity signal output structure 510 is configured to provide the electrical signal with the positive polarity to the first side S1 of the negative electrical adhesion-reducing adhesive structure to make the first side S1 the non-adhesion-reducing surface 220, and the second polarity signal output structure 520 is configured to provide the electrical signal with the negative polarity to the second side S2 of the negative electrical adhesion-reducing adhesive structure to make the second side S2 the adhesion-reducing surface 210; in this manner, the second side S2 of the negative electrical adhesion-reducing adhesive structure is separated from the bracket structure 10 when the electrical signal with the negative polarity is provided to the negative electrical adhesion-reducing adhesive structure. It can be understood that in the implementation shown in FIG. 4, the second polarity signal output structure 520 providing the electrical signal with the negative polarity for the second side S2 of the negative electrical adhesion-reducing adhesive structure is merely exemplary, but it is not limited to this. In other embodiments, the first polarity signal output structure 510 may also be configured to provide the electrical signal with the positive polarity to the second side S2 of the negative electrical adhesion-reducing adhesive structure to make the second side S2 the non-adhesion-reducing surface 220. At the same time, the second polarity signal output structure 520 is configured to provide the electrical signal with the negative polarity to the first side S1 of the negative electrical adhesion-reducing adhesive structure to make the first side S1 the adhesion-reducing surface 210; in this manner, the first side S1 of the negative electrical adhesion-reducing adhesive structure is separated from the back plate 40 when the electrical signal with the negative polarity is provided to the negative electrical adhesion-reducing adhesive structure.

It should be noted that FIG. 5 is a schematic sectional view of another display module provided by an embodiment of the present disclosure. Referring to FIG. 5, the display module may only include the first polarity signal output structure 510. When the first polarity signal output structure 510 is configured to provide the electrical signal with the positive polarity to the first side S1 of the negative electrical adhesion-reducing adhesive structure to make the first side S1 as the non-adhesion-reducing surface 220, the bracket structure 10 may also be grounded and in direct contact with the second side S2 of the negative electrical adhesion-reducing adhesive structure to provide the electrical signal with the negative polarity to the second side S2; thus the manner of providing the electrical signal with the negative polarity to the negative electrical adhesion-reducing adhesive structure is simple.

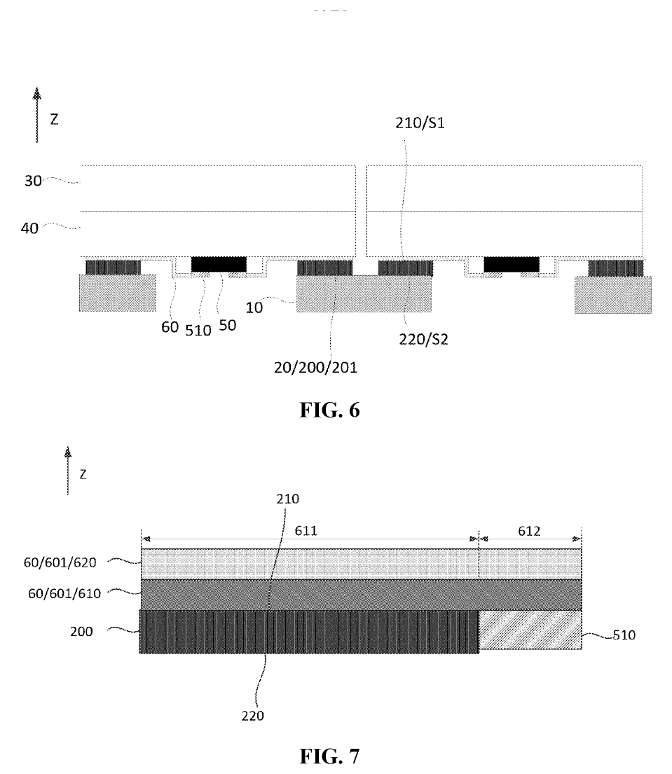

In one or more embodiments, based on the above embodiments, FIG. 6 is a schematic sectional view of another display module provided by an embodiment of the present disclosure. Referring to FIG. 6, the display module further includes an electrode structure 60 and a driver chip 50. The driver chip 50 includes at least one first polarity signal output structure 510. The electrode structure 60 is electrically connected to the adhesion-reducing surface 210 of the electrical adhesion-reducing adhesive structure 500 and the first polarity signal output structure 510, separately.

As shown in FIG. 6, the display module further includes the driver chip 50. The driver chip 50 may be disposed on the side of the back plate 40 facing away from the display panel 30. Furthermore, the bracket structure 10 may also include a hollowed-out area (not shown in the figure). The hollowed-out area at least partially overlaps the driver chip 50 along the thickness direction of the display module, thereby facilitating the arrangement of connection wires of the driver chip 50 to provide various signals for the display panel 30. Exemplarily, in the implementation shown in FIG. 6, the electrical adhesion-reducing adhesive structure 200 is the first polarity adhesion-reducing adhesive structure 201 (positive electrical adhesion-reducing adhesive structure), and the bracket structure 10 is grounded. The driver chip 50 includes at least one first polarity signal output structure 510. The driver chip 50 outputs the electrical signal with the positive polarity through the first polarity signal output structure 510. The first polarity signal output structure 510 is in contact with the first side S1 of the electrical adhesion-reducing adhesive structure 200 through the electrode structure 60 so that the first side S1 serves as the adhesion-reducing surface 210. The bracket structure 10 is in direct contact with the second side S2 of the electrical adhesion-reducing adhesive structure 200 so that the second side S2 serves as the non-adhesion-reducing surface 220. In this manner, the driver chip 50 is configured to provide the electrical signal with the positive polarity for the first polarity signal output structure 510, and the electrical signal with the positive polarity is transmitted through the electrode structure 60 to provide the electric field for the adhesion-reducing surface 210 of the first polarity adhesion-reducing adhesive structure 201, ensuring a simple transmission manner of the electrical signal.

It should be noted that, to better describe the present disclosure, the case where the electrical adhesion-reducing adhesive structure 200 is the first polarity adhesion-reducing adhesive structure 201 (positive electrical adhesion-reducing adhesive structure) and the bracket structure 10 provides the electrical signal with the negative polarity is taken as an example for description in the embodiments of the present disclosure, which will not be repeated.

In one or more embodiments, FIG. 7 is a partial structural schematic diagram of an electrode structure provided by an embodiment of the present disclosure. Referring to FIG. 7, the electrode structure 60 includes a first electrode structure 601. The first electrode structure 601 includes a first conductive layer 610 and a first substrate layer 620 disposed in a stacked manner. The first conductive layer 610 is located on the side of the first substrate layer 620 facing the electrical adhesion-reducing adhesive structure 200. The first conductive layer 610 includes a first connecting segment 611 and a second connecting segment 612. The first connecting segment 611 is in contact with and electrically connected to the adhesion-reducing surface 210, and the second connecting segment 612 is electrically connected to the first polarity signal output structure 510.

In the implementation shown in FIG. 7, the first electrode structure 601 includes the first conductive layer 610 and the first substrate layer 620. The first substrate layer 620 is located on the side of the first conductive layer 610 facing away from the electrical adhesion-reducing adhesive structure 200. While ensuring that the first conductive layer 610 is in contact with the electrical adhesion-reducing adhesive structure 200, the strength is provided for the first electrode structure 601 through the first substrate layer 620. The first conductive layer 610 includes the first connecting segment 611 in contact with the adhesion-reducing surface 210 and the second connecting segment 612 in contact with the first polarity signal output structure 510. When disassembly is required, the electrical signal with the positive polarity provided by the first polarity signal output structure 510 reaches the first connecting segment 611 through the second connecting segment 612, so that the electric field is provided to the adhesion-reducing surface 210 by the first connecting segment 611; thus, it is ensured that the back plate 40 is separated from the bracket structure 10. It can be understood that the first substrate layer 620 covers a third surface on the side of the first conductive layer 610 facing away from the electrical adhesion-reducing adhesive structure 200, and water and oxygen reaching the third surface are blocked by the first substrate layer 620 to prevent the third surface from being corroded by the water and oxygen. The adhesion-reducing surface 210 covers the surface on the side of the first connecting segment 611 facing the electrical adhesion-reducing adhesive structure 200. The first polarity signal output structure 510 covers the surface on the side of the second connecting segment 612 facing the electrical adhesion-reducing adhesive structure 200; that is, a fourth surface on the side of the first conductive layer 610 facing the electrical adhesion-reducing adhesive structure 200 is covered by the electrical adhesion-reducing adhesive structure 200 and the first polarity signal output structure 510, thus preventing the fourth surface from being corroded by the water and oxygen.

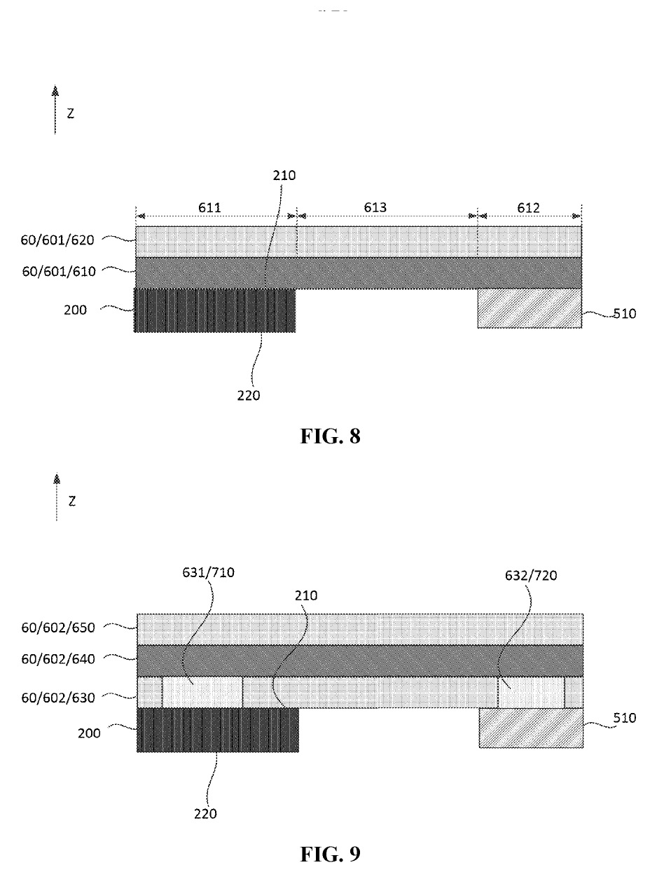

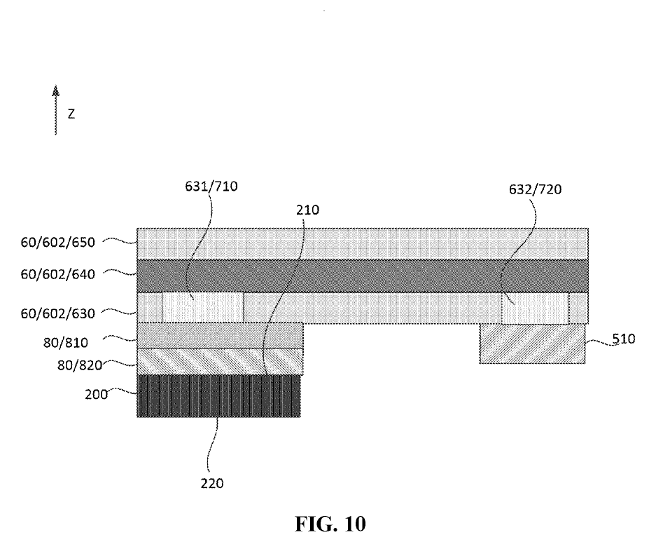

In one or more embodiments, FIG. 8 is a partial structural schematic diagram of another electrode structure provided by an embodiment of the present disclosure. Referring to FIGS. 1 and 8, the first conductive layer 610 further includes a third connecting segment 613. The third connecting segment 613 is connected to the first connecting segment 611 and the second connecting segment 612. Along the thickness direction Z of the display panel, the electrical adhesion-reducing adhesive structure 200 at least partially overlaps the first connecting segment 611, and the electrical adhesion-reducing adhesive structure 200 is staggered with the third connecting segment 613 and the second connecting segment 612.

Exemplarily, in the implementation shown in FIG. 8, the first conductive layer 610 includes the first connecting segment 611 at least partially overlapping the electrical adhesion-reducing adhesive structure 200, the second connecting segment 612 at least partially overlapping the first polarity signal output structure 510, and the third connecting segment 613 connected to the first connecting segment 611 and the second connecting segment 612. Along the thickness direction of the display module, the third connecting segment 613 is staggered with the electrical adhesion-reducing adhesive structure 200 and the first polarity signal output structure 510, that is, the surface on the side of the third connecting segment 613 facing away from the first substrate layer 620 is not provided with the electrical adhesion-reducing adhesive structure 200, so that the coverage area of the electrical adhesion-reducing adhesive structure 200 can be reduced while ensuring that the electrical adhesion-reducing adhesive structure 200 is provided with the electric field by the first conductive layer 610, and the production cost is reduced.

In one or more embodiments, FIG. 9 is a partial structural schematic diagram of another electrode structure provided by an embodiment of the present disclosure. Referring to FIG. 9, the electrode structure 60 includes a second electrode structure 602. The second electrode structure 602 includes a first protective layer 630, a second conductive layer 640, and a second substrate layer 650 disposed in a stacked manner. The first protective layer 630 includes a first through hole 631 and a second through hole 632. Along the thickness direction of the display module, the first through hole 631 at least partially overlaps the electrical adhesion-reducing adhesive structure 200. A first conductor 710 is disposed in the first through hole 631, and the first conductor 710 is in contact with the second conductive layer 640 and the electrical adhesion-reducing adhesive structure 200 separately. Along the thickness direction of the display module, the second through hole 632 at least partially overlaps the first polarity signal output structure 510. A second conductor 720 is disposed in the second through hole 632, and the second conductor 720 is in contact with the second conductive layer 640 and the first polarity signal output structure 510 separately.

Exemplarily, in the implementation shown in FIG. 9, the second electrode structure 602 includes the first protective layer 630, the second conductive layer 640 and the second substrate layer 650. The second substrate layer 650 covers a fifth surface on the side of the second conductive layer 640 facing away from the electrical adhesion-reducing adhesive structure 200 so that water and oxygen reaching the fifth surface are blocked by the second substrate layer 650 to prevent the fifth surface from being corroded by the water and oxygen. The first protective layer 630 covers a sixth surface on the side of the second conductive layer 640 facing the electrical adhesion-reducing adhesive structure 200 so that water and oxygen reaching the sixth surface are blocked by the first protective layer 630 to prevent the sixth surface from being corroded by the water and oxygen. It should be noted that the materials of the first protective layer 630 and the second substrate layer 650 may be the same or different, the present disclosure is not limited to this, and those skilled in the art may configure them as needed. Based on the above, since the first protective layer 630 and the second substrate layer 650 are not conductive, the first through hole 631 and the second through hole 632 are provided on the first protective layer 630 located on the side of the second conductive layer 640 facing the electrical adhesion-reducing adhesive structure 200. Along the thickness direction of the display module, the first through hole 631 penetrates through the first protective layer 630 and at least partially overlaps the electrical adhesion-reducing adhesive structure 200, so that after the first conductor 710 is disposed in the first through hole 631, the first conductor 710 can be electrically connected to the electrical adhesion-reducing adhesive structure 200 and the second conductive layer 640 separately. Similarly, along the thickness direction of the display module, the second through hole 632 penetrates through the first protective layer 630 and at least partially overlaps the first polarity signal output structure 510, so that after the second conductor 720 is disposed in the second through hole 632, the second conductor 720 can be electrically connected to the first polarity signal output structure 510 and the second conductive layer 640 separately. In this manner, when disassembly is needed, the electrical signal with the positive polarity provided by the first polarity signal output structure 510 can reach the adhesion-reducing surface 210 through the second conductor 720, the second conductive layer 640 and the first conductor 710 to reduce the adhesion of the adhesion-reducing surface 210, so that the back plate 40 is separated from the bracket structure 10.

In one or more embodiments, based on the above embodiments, FIG. 10 is a partial structural schematic diagram of another electrode structure provided by an embodiment of the present disclosure. Referring to FIG. 10, the display module further includes a conductive structure 80. The adhesion between the conductive structure 80 and the electrical adhesion-reducing adhesive structure 200 is greater than the adhesion between the first conductor 710 and the electrical adhesion-reducing adhesive structure 200, and the conductive structure 80 is electrically connected to the first conductor 710 and the electrical adhesion-reducing adhesive structure 200 separately. Specifically, in the embodiments of the present disclosure, the material of the first conductor 710 may include copper, and the material of the conductive structure 80 may include steel. Since the first conductor 710 made of copper has poor adhesion with the electrical adhesion-reducing adhesive structure 200 and is prone to being corroded by water and oxygen, resulting in a poor signal transmission effect, the conductive structure 80 is disposed between the first conductor 710 and the electrical adhesion-reducing adhesive structure 200, and the conductive structure 80 made of steel has good adhesion with the electrical adhesion-reducing adhesive structure 200 and is less susceptible to corrosion by water and oxygen. Therefore, the conductive structure 80 is used to assist the transmission of the electrical signal, thereby improving the transmission effect of the electrical signal.

It should be noted that, based on the above, with continued reference to FIG. 10, the conductive structure 80 includes a conductive adhesive layer 810 and a third conductive layer 820, and the third conductive layer 820 is located on the side of the conductive adhesive layer 810 facing away from the second conductive layer 640. In this manner, the third conductive layer 820 and the first conductor 710 are fixed by the conductive adhesive layer 810 so that the electrical signal with the positive polarity provided by the first polarity signal output structure 510 can reach the adhesion-reducing surface 210 through the second conductor 720, the second conductive layer 640, the first conductor 710, the conductive adhesive layer 810 and the third conductive layer 820, ensuring the normal transmission of signals.

In one or more embodiments, with continued reference to FIGS. 6 and 7, the first polarity signal output structure 510 includes a shielding output structure (not shown in the figure), and the electrode structure 60 is electrically connected to the driver chip 50 through the shielding output structure. Specifically, the shielding output structure can protect the part of the first polarity signal output structure 510 located in the driver chip 50 from being corroded by water and oxygen, thereby further improving the transmission effect of the electrical signal.

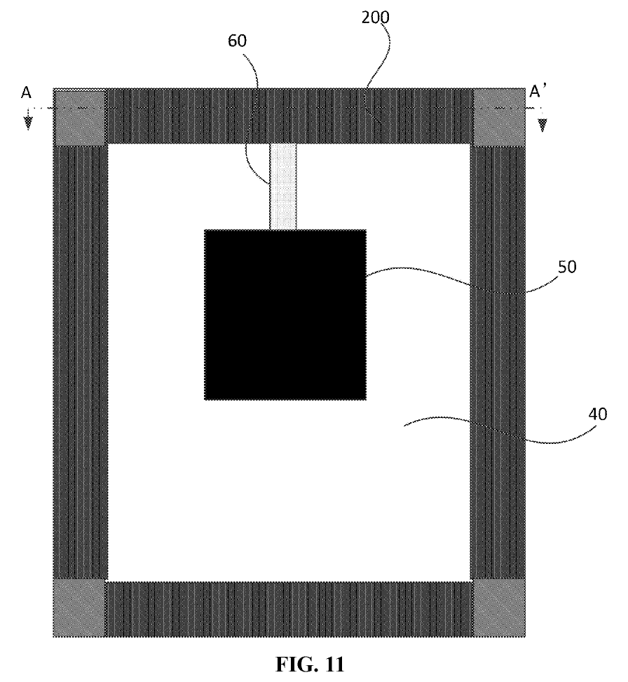

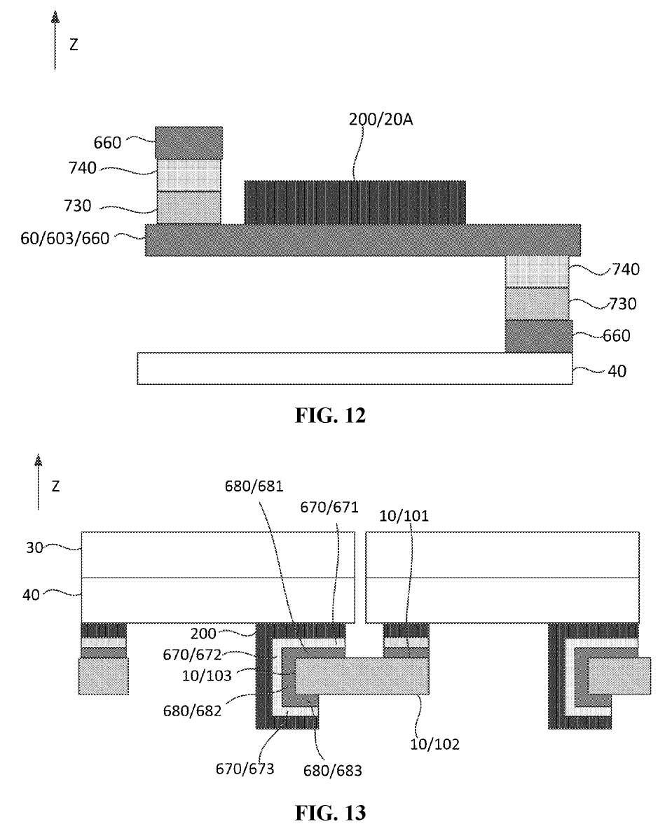

In one or more embodiments, on the basis of the above embodiments, FIG. 11 is a structural schematic diagram of a display module provided by an embodiment of the present disclosure, and FIG. 12 is a schematic sectional view along the direction AA' in FIG. 11. Referring to FIGS. 11 and 12, the electrical adhesion-reducing adhesive structure 200 on the same back plate 40 includes multiple electrical adhesion-reducing adhesive structure segments 20A, and the same back plate 40 includes multiple electrode structures 60. The electrode structure 60 includes a third electrode structure 603. The third electrode structure 603 includes a fourth conductive layer 660. The fourth conductive layer 660 includes a first surface on the side of the fourth conductive layer 660 facing away from the back plate 40 and a second surface on the side of the fourth conductive layer 660 facing the back plate 40. The first surface is provided with a first pad 730, and the second surface is provided with a second pad 740. The first pad 730 and the second pad 740 are located at different sides of the fourth conductive layer 660 along the direction of the plane where the back plate 40 is located. The first pad 730 and the second pad 740 are staggered with the electrical adhesion-reducing adhesive structure 200 along the thickness direction Z of the display panel. In two adjacent third electrode structures 603, the first pad 730 of one third electrode structure 603 is electrically connected to the second pad 740 of the other third electrode structure 603.

Specifically, in the implementation shown in FIGS. 11 and 12, the third electrode structure 603 includes the fourth conductive layer 660. The first pad 730 is located on the first surface on the side of the fourth conductive layer 660 facing away from the back plate 40, the second pad 740 is located on the second surface on the side of the fourth conductive layer 660 facing the back plate 40, and the first pad 730 and the second pad 740 are located on different sides of the electrical adhesion-reducing adhesive structure 200. In this manner, in the corner position of the back plate 40, two adjacent third electrode structures 603 may be configured so that the first pad 730 of one third electrode structure 603 is electrically connected to the second pad 740 of the other third electrode structure 603, enabling the two third electrode structures 603 located in the corner position of the back plate 40 to be electrically connected through the first pad 730 and the second pad 740. Furthermore, a tiled electrode structure with a set shape and size may be tiled and cascaded by providing multiple lapping third electrode structures 603 so that the arrangement and connection of the electrode structures 60 on the back plate 40 are simple. Furthermore, since the first pad 730 and the second pad 740 are staggered with the electrical adhesion-reducing adhesive structure 200 along the thickness direction Z of the display panel, no electrical adhesion-reducing adhesive structure 200 is required at the overlapping position of two adjacent third electrode structures 603, thus reducing the production cost.

In one or more embodiments, based on the above embodiments, FIG. 13 is a structural schematic diagram of another display module provided by an embodiment of the present disclosure. Referring to FIG. 13, the electrode structure 60 includes a fourth electrode structure 604. The fourth electrode structure 604 includes a fifth conductive layer 670. The bracket structure 10 includes a first main surface 101 on the side of the bracket structure 10 facing the back plate 40, a second main surface 102 on the side of the bracket structure 10 facing away from the back plate 40, and a side surface 103 connecting the first main surface 101 and the second main surface 102. The fifth conductive layer 670 includes a first conductive segment 671 located on the first main surface 101, a second conductive segment 672 located on the side surface 103, and a third conductive segment 673 located on the second main surface 102. The second conductive segment 672 is electrically connected to the first conductive segment 671 and the third conductive segment 673 separately. The electrical adhesion-reducing adhesive structure 200 is located on the side of the fifth conductive layer 670 facing away from the bracket structure 10, and the electrical adhesion-reducing adhesive structure 200 covers at least part of the fifth conductive layer 670.

Exemplarily, in the implementation shown in FIG. 13, the bracket structure 10 includes the first main surface 101, the second main surface 102, and multiple side surfaces 103. The first main surface 101 and the second main surface 102 are oppositely disposed, and the multiple side surfaces 103 are connected to the first main surface 101 and the second main surface 102. The first main surface 101 is the surface of the bracket structure 10 facing the back plate 40, and the second main surface 102 is the surface of the bracket structure 10 facing away from the back plate 40, that is, the first main surface 101 is bonded to the back plate 40 through the electrical adhesion-reducing adhesive structure 200. Therefore, the electrode structure 60 is required to be disposed between the first main surface 101 and the back plate 40. However, due to the limitation of the space between the first main surface 101 and the back plate 40, the signal transmission manner of the electrode structure 60 is limited. In this regard, the electrode structure 60 is configured to include the fourth electrode structure 604, and the fourth electrode structure 604 includes the fifth conductive layer 670. That is, the fifth conductive layer 670 includes the first conductive segment 671 located on the first main surface 101, the second conductive segment 672 located on the side surface 103, and the third conductive segment 673 located on the second main surface 102. The second conductive segment 672 is electrically connected to the first conductive segment 671 and the third conductive segment 673 separately. Therefore, the fifth conductive layer 670 is bent along the first main surface 101 and the side surface 103 to the second main surface 102 to transmit the signal to the electrode structure 60 through the second main surface 102 on the side of the bracket structure 10 facing away from the back plate 40.

It should be noted that a schematic sectional view is exemplarily described in FIG. 13. Therefore, the connection relationship between the electrical adhesion-reducing adhesive structures 200 corresponding to the same back plate 40 is not reflected in the figure. It is obvious to those skilled in the art that the electrical adhesion-reducing adhesive structures 200 corresponding to the same back plate 40 may be an integrated structure, and similarly, the fourth electrode structure 604 disposed corresponding to the electrical adhesion-reducing adhesive structures 200 is also an integrated structure. Furthermore, on the same back plate 40, as long as the fourth electrode structure 604 is bent to the second main surface 102 of the bracket structure 10 at one position, the electrical signal can be provided for all the electrical adhesion-reducing adhesive structures 200 on the same back plate 40.

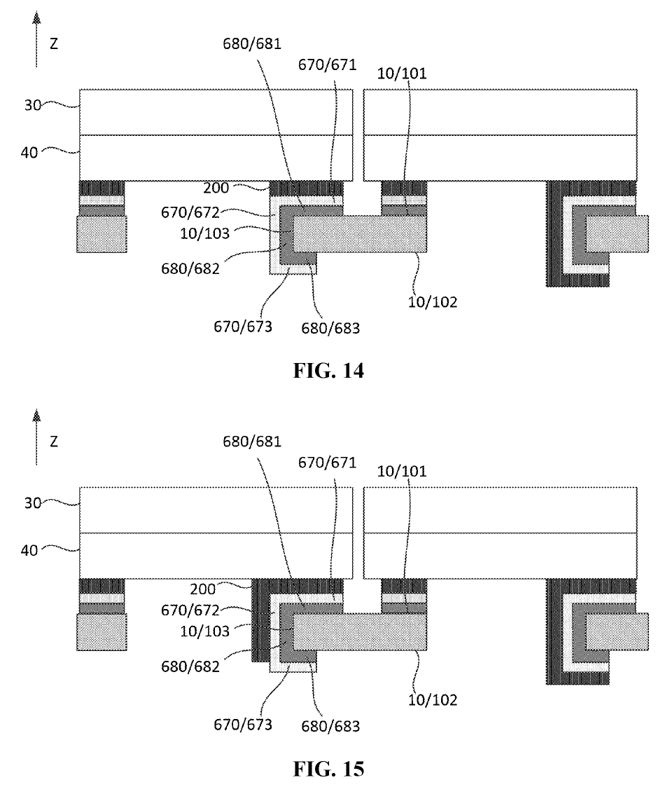

It can be understood that the electrical adhesion-reducing adhesive structure 200 may be located on the side of the fifth conductive layer 670 facing away from the bracket structure 10, and the electrical adhesion-reducing adhesive structure 200 covers at least part of the fifth conductive layer 670. In the implementation shown in FIG. 13, the case where the electrical adhesion-reducing adhesive structure 200 covers the first conductive segment 671, the second conductive segment 672 and the third conductive segment 673 is taken as an example, but it is not limited to this. In other embodiments, FIG. 14 is a structural schematic diagram of another display module provided by an embodiment of the present disclosure. Referring to FIG. 14, the electrical adhesion-reducing adhesive structure 200 may only cover the first conductive segment 671. Alternatively, FIG. 15 is a structural schematic diagram of another display module provided by an embodiment of the present disclosure. Referring to FIG. 15, the electrical adhesion-reducing adhesive structure 200 may cover the first conductive segment 671 and part of the second conductive segment 672, and those skilled in the art may configure it as needed.

In one or more embodiments, with continued reference to FIG. 13, the display module further includes an adhesive layer 680. The adhesive layer 680 is located on the side of the fifth conductive layer 670 facing the bracket structure 10. Since the fifth conductive layer 670 does not have adhesion, the adhesive layer 680 includes a first adhesive segment 681, a second adhesive segment 682 and a third adhesive segment 683, such that the first conductive segment 671 is fixed on the first main surface 101 through the first adhesive segment 681, the second conductive segment 672 is fixed on the side surface 103 through the second adhesive segment 682, and the third adhesive segment 683 is fixed on the second main surface 102 through the third adhesive segment 683. It can be understood that the first adhesive segment 681, the second adhesive segment 682 and the third adhesive segment 683 may be provided independently or integrally, and the embodiments of the present disclosure are not limited to this, as long as each segment of the fifth conductive layer 670 is fixed on the surface of the bracket structure 10 through the adhesive layer 680.

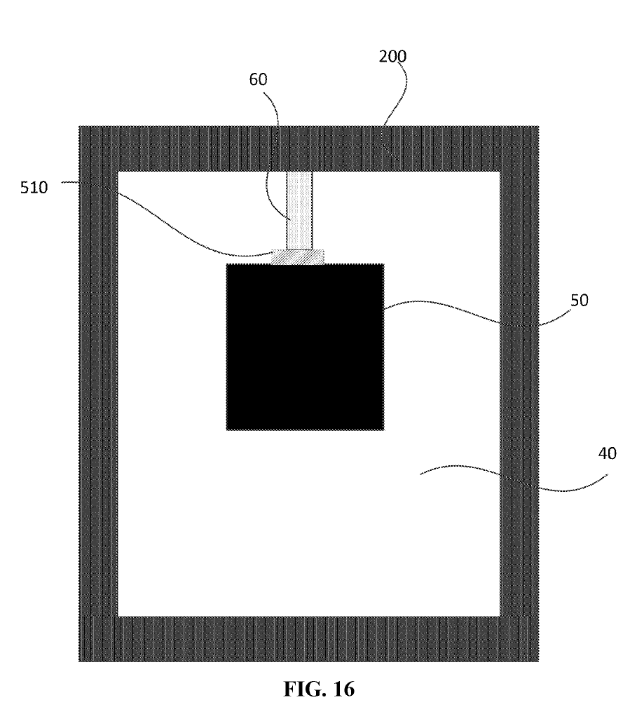

In one or more embodiments, based on the above embodiments, FIG. 16 is a structural schematic diagram of another display module provided by an embodiment of the present disclosure. As shown in FIG. 16, the electrical adhesion-reducing adhesive structure 200 on the same back plate 40 is an integrated structure. At least one electrode structure 60 is included on the same back plate. At least one first polarity signal output structure 510 is configured to provide the electrical signal with the first polarity to the electrical adhesion-reducing adhesive structure 200 through a respective electrode structure 60.

As shown in FIGS. 1 and 16, the back plate 40 is provided with a driver chip 50. The electrical adhesion-reducing adhesive structure 200 on the same back plate 40 may be disposed around the driver chip 50; in other words, the electrical adhesion-reducing adhesive structure 200 is disposed around the edge of the back plate 40, so that the uniformity of the adhesion between the back plate 40 and the bracket structure 10 is ensured under the normal condition. When disassembly is required, the uniformity of adhesion reduction at the edge of the back plate 40 is ensured. Furthermore, the electrical adhesion-reducing adhesive structure 200 on the same back plate 40 is provided as an integrated structure so that the driver chip 50 can provide the electrical signal with the first polarity for the electrical adhesion-reducing adhesive structure 200 around the driver chip 50 through one first polarity signal output structure 510 and one electrode structure 60; thus, the number of first polarity signal output structures 510 and the number of electrode structures 60 can be reduced while ensuring that the transmission manner of the electrical signal is simple, and thus the production cost is reduced.

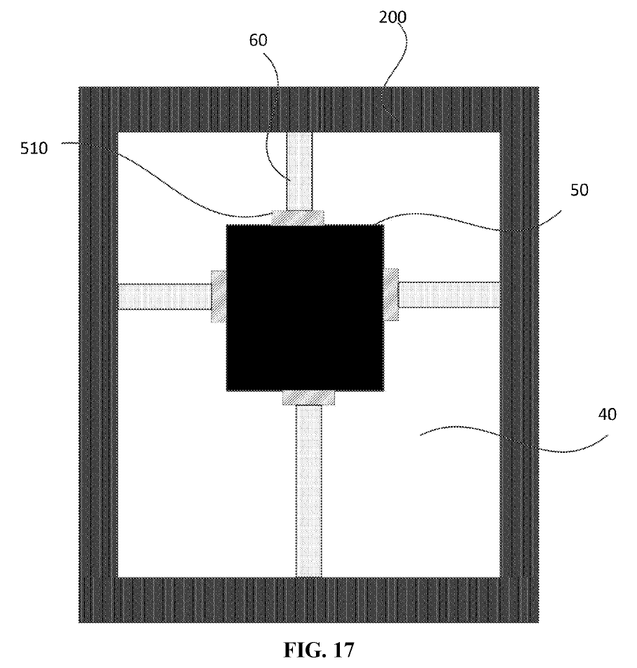

In one or more embodiments, FIG. 17 is a structural schematic diagram of another display module provided by an embodiment of the present disclosure. Referring to FIG. 17, the driver chip 50 includes multiple first polarity signal output structures 510. The multiple first polarity signal output structures 510 are located at different sides of the driver chip 50. The same back plate 40 includes multiple electrode structures 60, and the first polarity signal output structures 510 are configured to provide the electrical signal with the first polarity for the electrical adhesion-reducing adhesive structure 200 through the electrode structures 60.

Exemplarily, in the implementation shown in FIG. 17, the driver chip 50 includes multiple first polarity signal output structures 510, and different first polarity signal output structures 510 are located at different sides of the driver chip 50. The same back plate 40 further includes multiple electrode structures 60. The multiple electrode structures 60 are located at different sides of the driver chip 50 so that the driver chip 50 can provide the electrical signal with the first polarity to the electrical adhesion-reducing adhesive structure 200 on the respective side edge through the respective first polarity signal output structure 510 and the respective electrode structure 60. For example, as shown in FIG. 15, the first polarity signal output structure 510 located on the left side of the driver chip 50 is configured to provide the electrical signal with the first polarity to part of the electrical adhesion-reducing adhesive structure 200 located on the left side edge of the back plate 40 through the respective electrode structure 60. The first polarity signal output structure 510 located on the right side of the driver chip 50 is configured to provide the electrical signal with the first polarity to part of the electrical adhesion-reducing adhesive structure 200 located on the right side edge of the back plate 40 through the respective electrode structure 60. The first polarity signal output structure 510 located on the upper side of the driver chip 50 is configured to provide the electrical signal with the first polarity to part of the electrical adhesion-reducing adhesive structure 200 located on the upper side edge of the back plate 40 through the respective electrode structure 60. The first polarity signal output structure 510 located on the lower side of the driver chip 50 is configured to provide the electrical signal with the first polarity to part of the electrical adhesion-reducing adhesive structure 200 located on the lower side edge of the back plate 40 through the respective electrode structure 60. Thus, the electrical adhesion-reducing adhesive structure 200 around the back plate 40 is connected to the first polarity signal output structure 510 of the driver chip 50 through the respective electrode structures 60 to ensure the uniformity of the potential on the electrical adhesion-reducing adhesive structure 200.

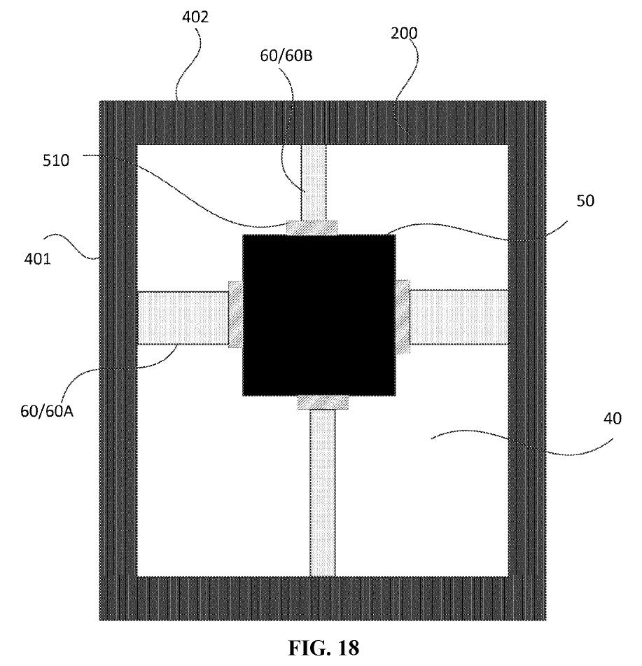

In one or more embodiments, on the basis of the above embodiments, FIG. 18 is a structural schematic diagram of another display module provided by an embodiment of the present disclosure. Referring to FIG. 18, the back plate 40 includes a first side edge 401 and a second side edge 402. An extension length of the electrical adhesion-reducing adhesive structure 200 at the first side edge 401 is greater than an extension length of the electrical adhesion-reducing adhesive structure 200 at the second side edge 402. The multiple electrode structures 60 include a first sub-electrode structure 60A and a second sub-electrode structure 60B. The first sub-electrode structure 60A is in contact with the electrical adhesion-reducing adhesive structure 200 on the first side edge 401. The second sub-electrode structure 60B is in contact with the electrical adhesion-reducing adhesive structure 200 on the second side edge 402. A line width of the first sub-electrode structure 60A is larger than a line width of the second sub-electrode structure 60B.

As shown in FIG. 18, if the overall shape of the back plate 40 is rectangular, the back plate 40 includes the first side edges 401 and the second side edges 402. The length of the first side edge 401 is greater than the length of the second side edge 402, and the extension length of the part of the electrical adhesion-reducing adhesive structure 200 located at the first side edge 401 is greater than the extension length of the part of the electrical adhesion-reducing adhesive structure 200 located at the second side edge 402. The back plate 40 is further provided with the first sub-electrode structures 60A and the second sub-electrode structures 60B. The driver chip 50 is configured to provide the electrical signal with the first polarity to the electrical adhesion-reducing adhesive structure 200 on the first side edge 401 through the first sub-electrode structure 60A and provide the electrical signal with the first polarity to the electrical adhesion-reducing adhesive structure 200 on the second side edge 402 through the second sub-electrode structure 60B. The transmission speed of the electrical signal is related to the extension length of the electrical adhesion-reducing adhesive structure 200 on the side edge and the line width of the electrode structure 60, and the line width of the first sub-electrode structure 60A is configured to be greater than the line width of the second sub-electrode structure 60B so that a first ratio between the line width of the first sub-electrode structure 60A and the extension length of the electrical adhesion-reducing adhesive structure 200 on the first side edge 401 is approximately the same as a second ratio between the line width of the second sub-electrode structure 60B and the extension length of the electrical adhesion-reducing adhesive structure 200 on the second side edge 402, thereby ensuring that the transmission speed of the signal on each side edge of the back plane 40 is approximately the same.

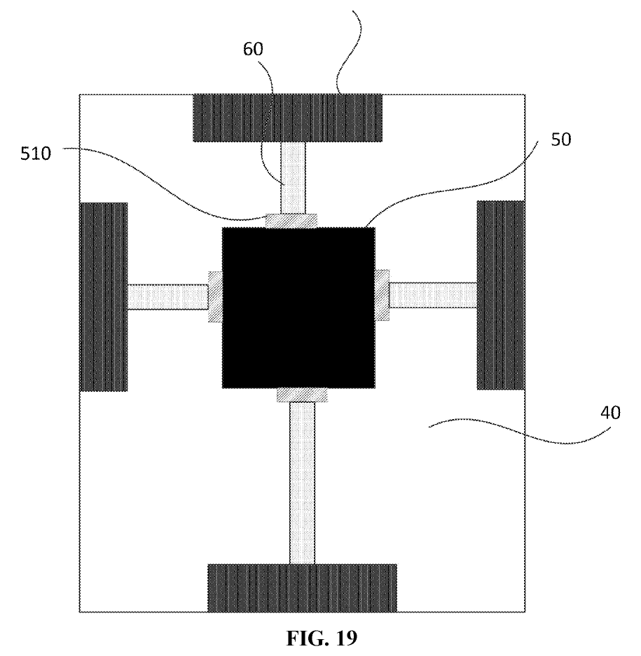

In one or more embodiments, based on the above embodiments, FIG. 19 is a structural schematic diagram of another display module provided by an embodiment of the present disclosure. Referring to FIG. 19, the electrical adhesion-reducing adhesive structure 200 on the same back plate 40 includes multiple electrical adhesion-reducing adhesive structure segments 20A, and the multiple electrical adhesion-reducing adhesive structure segments 20A are independently disposed. Specifically, in the implementation shown in FIG. 19, the multiple electrical adhesion-reducing adhesive structure segments 20A are independently disposed, that is, a gap exists between different electrical adhesion-reducing adhesive structure segments 20A, so that the coverage area of the electrical adhesion-reducing adhesive structure 200 can be reduced and the production cost can be reduced.

On the basis of the above, with continued reference to FIG. 19, the multiple electrical adhesion-reducing adhesive structure segments 20A on the same back plate 40 are located at different sides of the driver chip 50. The same back plate 40 includes multiple electrode structures 60. The first polarity signal output structure 510 is configured to provide the electrical signal with the first polarity to an electrical adhesion-reducing adhesive structure segment 20A through the respective electrode structure 60.

Specifically, the driver chip 50 includes multiple first polarity signal output structures 510, and the multiple first polarity signal output structures 510 are located at different sides of the driver chip 50. The multiple electrical adhesion-reducing adhesive structure segments 20A on the same back plate 40 are located at different sides of the driver chip 50. Furthermore, the same back plate 40 further includes the multiple electrode structures 60, and then the driver chip 50 is configured to provide the electrical signal with the first polarity to a respective electrical adhesion-reducing adhesive structure segment 20A on a side through the first polarity signal output structure 510 and the electrode structures 60 on the side. For example, the driver chip 50 is configured to provide the electrical signal with the first polarity to the electrical adhesion-reducing adhesive structure segment 20A on the left side of the back plate 40 through the first polarity signal output structure 510 and the electrode structure 60 on the left side of the driver chip 50. The driver chip 50 is configured to provide the electrical signal with the first polarity to the electrical adhesion-reducing adhesive structure segment 20A on the right side of the back plate 40 through the first polarity signal output structure 510 and the electrode structure 60 on the right side of the driver chip 50, etc., thus ensuring that the driver chip 50 can provide the electrical signal to the multiple electrical adhesion-reducing adhesive structure segments 20A simultaneously. It should be noted that the driver chip 50 may provide the same electrical signal for the multiple electrical adhesion-reducing adhesive structure segments 20A, or may provide different electrical signals for the multiple electrical adhesion-reducing adhesive structure segments 20A, which is not limited by the present disclosure, and those skilled in the art may configure it as needed.

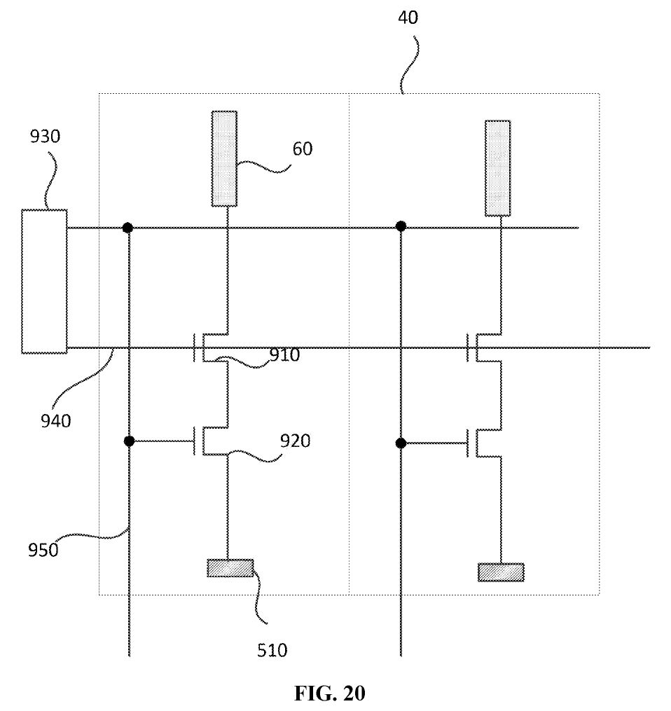

In one or more embodiments, based on the above embodiments, FIG. 20 is a functional schematic diagram of a driver chip provided by an embodiment of the present disclosure. Referring to FIG. 20, the display module further includes multiple row control switches 910, multiple column control switches 920, multiple electrode structures 60, and a switch control unit 930. The row control switches 910 and the column control switches 920 are disposed in a correspondence with the back plates 40. An electrode structure 60 is electrically connected to a first polarity signal output structure 510 through a row control switch 910 and a column control switch 920 connected in series. The switch control unit 930 is electrically connected to control terminals of the row control switches 910 and control terminals of the column control switches 920.

Specifically, the driver chip on each back plate may be provided with one row control switch 910 and one column control switch 920, the row control switch 910 and the column control switch 920 are connected in series between an output terminal of the first polarity signal output structure 510 and an input terminal of the electrode structure 60, and the switch control unit 930 is electrically connected to the control terminal of the row control switch 910 and the control terminal of the column control switch 920. In this manner, when it is determined that the back plate is required to be disassembled, the row control switch 910 and the column control switch 920 on the respective back plate are controlled to be turned on by the switch control unit 930 so that the electrical signal output by the first polarity signal output structure 510 can reach the electrode structure 60 through the row control switch 910 and the column control switch 920 to control the respective back plate to be disassembled. When any one of the row control switch 910 and the column control switch 920 on the respective back plate is not turned on, the electrical signal output by the first polarity signal output structure 510 cannot be transmitted to the electrode structure 60, and the respective back plate remains fixed to the bracket structure. Therefore, the row control switch 910 and the column control switch 920 are connected in series with the electrode structure 60 and the first polarity signal output structure 510 so that the disassembly of the respective back plate can be controlled only after the row position and the column position of the back plate are determined, thus ensuring the accuracy of the disassembly.

In one or more embodiments, with continued reference to FIG. 20, the display module further includes multiple row control electrodes 940 and multiple column control electrodes 950, and the extension direction of the row control electrodes 940 intersects with the extension direction of the column control electrodes 950. The row control electrodes 940 are electrically connected to a control terminal of the switch control unit 930 and the control terminals of the row control switches 910, separately. The column control electrodes 950 are electrically connected to the control terminal of the switch control unit 930 and the control terminals of the column control switches 920, separately.

Specifically, the extension direction of the row control electrodes 940 intersects with the extension direction of the column control electrodes 950. The intersection positions of the row control electrodes 940 and the column control electrodes 950 correspond to the positions of the back plates 40. In this manner, after the position of a to-be-disassembled back plate 40 is determined, an on signal from the switch control unit 930 is transmitted to the control terminal of the row control switch 910 on the respective back plate 40 through the row control electrode 940 corresponding to the position of the back plate 40 to control the row control switch 910 to be turned on. At the same time, the on signal from the switch control unit 930 is transmitted to the control end of the column control switch 920 on the respective back plate 40 through the column control electrode 950 corresponding to the position of the back plate 40 to control the column control switch 920 to be turned on. In this manner, the electrical signal output by the first polarity signal output structure 510 is transmitted to the electrode structure 60 corresponding to the back plate 40 to separate the respective back plate 40 from the bracket structure 10.

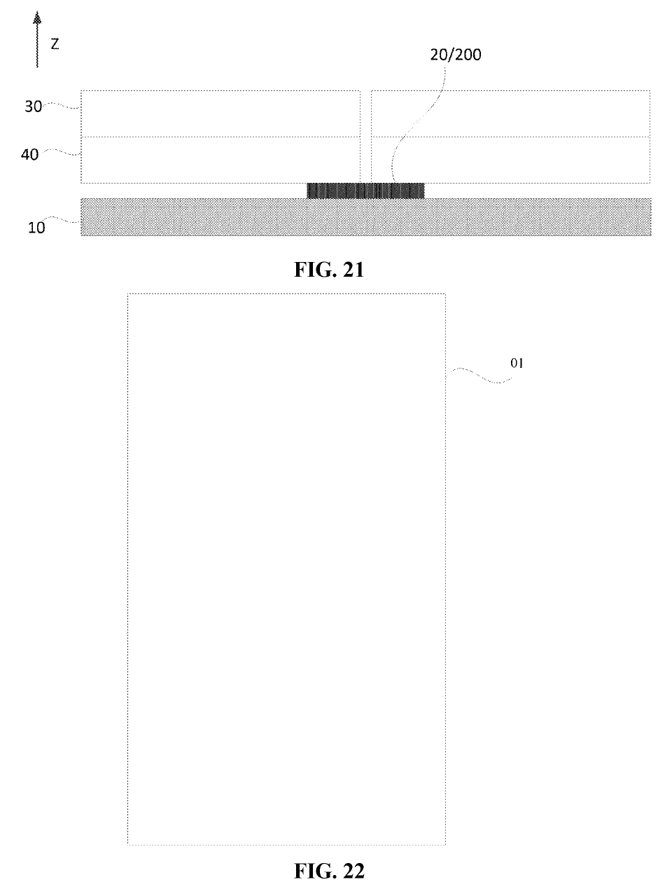

In one or more embodiments, based on the above embodiments, and with continued reference to FIG. 1, the adhesion-reducing adhesive structures 20 on different back plates 40 are independently disposed. In this manner, after the specific condition is applied to multiple adhesion-reducing adhesive structures 20 between certain back plates 40 and the bracket structure 10, the adhesion of the multiple adhesion-reducing adhesive structures 20 is reduced, thereby realizing the disassembly between one back plate 40 and the bracket structure 10. It can be understood that the present disclosure is not limited to this. In other embodiments, FIG. 21 is a schematic sectional view of another display module provided by an embodiment of the present disclosure. Referring to FIG. 21, along the thickness direction Z of the display panel, the adhesion-reducing adhesive structure 20 may also cover the splicing gap of two adjacent display panels 30 and at least partially overlap two adjacent display panels 30. Furthermore, after the specific condition is applied to the adhesion-reducing adhesive structure 20 at the splicing gap, the splicing gap may be separated from the bracket structure 10.

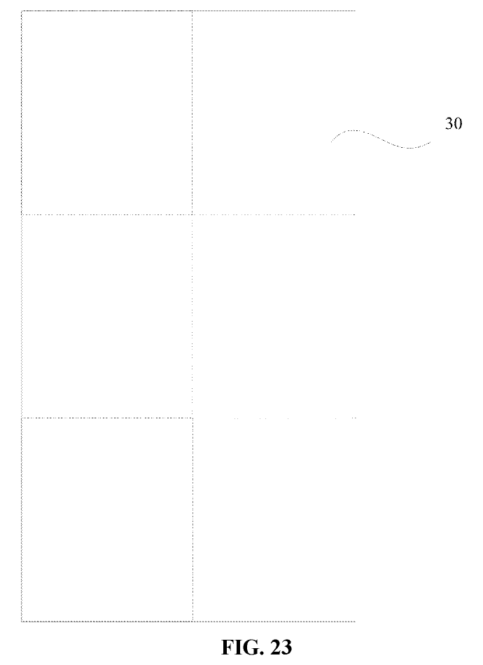

Based on the same inventive concept as above, an embodiment of the present disclosure further provides a display device. FIG. 22 is a structural schematic diagram of a display device provided by an embodiment of the present disclosure. As shown in FIG. 22, the display device includes the display module 01 described in any of the above embodiments. Therefore, the display device provided by the embodiments of the present disclosure has the corresponding beneficial effects of the display module 01 provided by the embodiments of the present disclosure, which will not be repeated. Exemplarily, the display device may be an electronic device such as a mobile phone, a computer, a smart wearable device (for example, a smart watch), and an in-vehicle display device. Furthermore, in other embodiments, FIG. 23 is a structural schematic diagram of another display device provided by an embodiment of the present disclosure. As shown in FIG. 23, the display device may also be a tiled display device, and the tiled display device is formed by splicing multiple display panels 30.

Note that the above are only the preferred embodiments of the present disclosure and the technical principles employed. Those skilled in the art will understand that the present disclosure is not limited to the specific embodiments described herein, and various obvious changes, readjustments and substitutions will be obvious to those skilled in the art without departing from the scope of protection of the present disclosure. Therefore, although the present disclosure has been described in detail through the above embodiments, the present disclosure is not limited to the above embodiments, but may include many other equivalent embodiments without departing from the concept of the present disclosure, and the scope of the present disclosure is determined by the scope of the appended claims.

What is claimed is:

1. A display module, comprising a bracket structure, an adhesion-reducing adhesive structure, a plurality of display panels and a plurality of back plates, wherein
the plurality of back plates are disposed on a non-light-emission side of the plurality of display panels; and
the bracket structure is disposed on a side of the plurality of back plates facing away from the plurality of display panels through the adhesion-reducing adhesive structure, and adhesion of the adhesion-reducing adhesive structure is variable.

2. The display module according to claim 1, wherein the adhesion-reducing adhesive structure comprises an electrical adhesion-reducing adhesive structure; wherein
the electrical adhesion-reducing adhesive structure comprises an adhesion-reducing surface and a non-adhesion-reducing surface disposed opposite to each other; and adhesion of the adhesion-reducing surface is variable;
wherein the electrical adhesion-reducing adhesive structure comprises a first polarity adhesion-reducing adhesive structure;
the display module further comprises a first polarity signal output structure and a second polarity signal output structure; and
the first polarity signal output structure is configured to provide an electrical signal with a first polarity for the adhesion-reducing surface, and the second polarity signal output structure is configured to provide an electrical signal with a second polarity for the non-adhesion-reducing surface; wherein the first polarity is opposite to the second polarity.

3. The display module according to claim 2, further comprising an electrode structure and a driver chip, wherein
the driver chip comprises at least one first polarity signal output structure; and
the electrode structure is electrically connected to the adhesion-reducing surface of the electrical adhesion-reducing adhesive structure and the at least one first polarity signal output structure.

4. The display module according to claim 3, wherein the electrode structure comprises a first electrode structure;
the first electrode structure comprises a first conductive layer and a first substrate layer disposed in a stacked manner, and the first conductive layer is located at a side of the first substrate layer facing the electrical adhesion-reducing adhesive structure; and
the first conductive layer comprises a first connecting segment and a second connecting segment, the first connecting segment is in contact with and electrically connected to the adhesion-reducing surface, and the second connecting segment is electrically connected to the at least one first polarity signal output structure.

5. The display module according to claim 4, wherein the first conductive layer further comprises a third connecting segment, and the third connecting segment is connected to the first connecting segment and the second connecting segment; and
along a thickness direction of the plurality of display panels, the electrical adhesion-reducing adhesive structure at least partially overlaps the first connecting segment, and the electrical adhesion-reducing adhesive structure is staggered with the third connecting segment and the second connecting segment.

6. The display module according to claim 3, wherein the electrode structure comprises a second electrode structure;
the second electrode structure comprises a first protective layer, a second conductive layer and a second substrate layer disposed in a stacked manner;
the first protective layer comprises a first through hole and a second through hole, the first through hole at least partially overlaps the electrical adhesion-reducing adhesive structure along a thickness direction of the the plurality of display panels, a first conductor is disposed in the first through hole, and the first conductor is in contact with the second conductive layer and the electrical adhesion-reducing adhesive structure, separately; and
the second through hole at least partially overlaps the at least one first polarity signal output structure along the thickness direction of the plurality of display panels, a second conductor is disposed in the second through hole, and the second conductor is in contact with the second conductive layer and the at least one first polarity signal output structure, separately.

7. The display module according to claim 6, further comprising a conductive structure, wherein
adhesion between the conductive structure and the electrical adhesion-reducing adhesive structure is greater than adhesion between the first conductor and the electrical adhesion-reducing adhesive structure; and
the conductive structure is electrically connected to the first conductor and the electrical adhesion-reducing adhesive structure, separately.

8. The display module according to claim 7, wherein the conductive structure comprises a conductive adhesive layer and a third conductive layer, and the third conductive layer is located at a side of the conductive adhesive layer facing away from the second conductive layer.

9. The display module according to claim 3, wherein a first polarity signal output structure of the at least one first polarity signal output structure comprises a shielding output structure, and the electrode structure is electrically connected to the driver chip through the shielding output structure.

10. The display module according to claim 3, wherein the electrical adhesion-reducing adhesive structure on a same back plate among the plurality of back plates comprises a plurality of electrical adhesion-reducing adhesive structure segments, and the same back plate comprises a plurality of electrode structures;
an electrode structure of the plurality of electrode structures comprises a third electrode structure;
the third electrode structure comprises a fourth conductive layer, and the fourth conductive layer comprises a first surface on a side of the fourth conductive layer facing the same back plate and a second surface on a side of the fourth conductive layer facing away from the same back plate;
the first surface is provided with a first pad, the second surface is provided with a second pad, the first pad and the second pad are located at different sides of the fourth conductive layer along a direction of a plane where the back plate is located, and the first pad and the second pad are staggered with the electrical adhesion-reducing adhesive structure along a thickness direction of the plurality of display panels; and
in two adjacent third electrode structures, the first pad of one third electrode structure is electrically connected to the second pad of the other third electrode structure.

11. The display module according to claim 3, wherein the electrode structure comprises a fourth electrode structure, and the fourth electrode structure comprises a fifth conductive layer;
the bracket structure comprises a first main surface on a side of the bracket structure facing the plurality of back plates, a second main surface on a side of the bracket structure facing away from the plurality of back plates, and a side surface connecting the first main surface and the second main surface;
the fifth conductive layer comprises a first conductive segment located on the first main surface, a second conductive segment located on the side surface and a third conductive segment located on the second main surface, wherein the second conductive segment is electrically connected to the first conductive segment and the third conductive segment; and
the electrical adhesion-reducing adhesive structure is located on a side of the fifth conductive layer facing away from the bracket structure, and the electrical adhesion-reducing adhesive structure covers at least part of the fifth conductive layer.

12. The display module according to claim 11, further comprising an adhesive layer, wherein
the adhesive layer is located at a side of the fifth conductive layer facing the bracket structure;
the adhesive layer comprises a first adhesive segment, a second adhesive segment and a third adhesive segment; and
the first conductive segment is fixed on the first main surface through the first adhesive segment, the second conductive segment is fixed on the side surface through the second adhesive segment, and the third conductive segment is fixed on the second main surface through the third adhesive segment.

13. The display module according to claim 3, wherein the electrical adhesion-reducing adhesive structure on a same back plate among the plurality of back plates is an integrated structure;
the same back plate comprises at least one electrode structure; and
the at least one first polarity signal output structure is configured to provide an electrical signal with a first polarity for the electrical adhesion-reducing adhesive structure through the at least one electrode structure.

14. The display module according to claim 13, wherein the driver chip comprises a plurality of first polarity signal output structures, and the plurality of first polarity signal output structures are located at different sides of the driver chip;
the same back plate comprises a plurality of electrode structures; and
a first polarity signal output structure of the plurality of first polarity signal output structures is configured to provide the electrical signal with the first polarity for the electrical adhesion-reducing adhesive structure through a respective electrode structure of the plurality of electrode structures.

15. The display module according to claim 14, wherein the same back plate comprises a first side edge and a second side edge, and an extension length of the electrical adhesion-reducing adhesive structure at the first side edge is greater than an extension length of the electrical adhesion-reducing adhesive structure at the second side edge; and
the plurality of the electrode structures comprise a first sub-electrode structure and a second sub-electrode structure, the first sub-electrode structure is in contact with the electrical adhesion-reducing adhesive structure on the first side edge, the second sub-electrode structure is in contact with the electrical adhesion-reducing adhesive structure on the second side edge, and a line width of the first sub-electrode structure is larger than a line width of the second sub-electrode structure.

16. The display module according to claim 3, wherein the electrical adhesion-reducing adhesive structure on a same back plate of the plurality of back plates comprises a plurality of electrical adhesion-reducing adhesive structure segments, and the plurality of electrical adhesion-reducing adhesive structure segments are independently disposed.

17. The display module according to claim 16, wherein the plurality of electrical adhesion-reducing adhesive structure segments on the same back plate are located at different sides of the driver chip;
the same back plate comprises a plurality of electrode structures; and
the at least one first polarity signal output structure is configured to provide an electrical signal with a first polarity for an electrical adhesion-reducing adhesive structure segment among the plurality of electrical adhesion-reducing adhesive structure segments through a respective electrode structure of the plurality of electrode structures.

18. The display module according to claim 3, further comprising a plurality of row control switches, a plurality of column control switches, a plurality of electrode structures and a switch control unit, wherein
the plurality of row control switches and the plurality of column control switches are disposed in a correspondence with the plurality of back plates;
an electrode structure of the plurality of electrode structures is electrically connected to the at least one first polarity signal output structure through a row control switch of the plurality of row control switches and a column control switch of the plurality of column control switches, and the row control switch and the column control switch are connected in series; and
the switch control unit is electrically connected to control terminals of the plurality of row control switches and control terminals of the plurality of column control switches.

19. The display module according to claim 18, further comprising a plurality of row control electrodes and a plurality of column control electrodes, wherein
an extension direction of the plurality of row control electrodes intersects with an extension direction of the plurality of column control electrodes; and
the plurality of row control electrodes are electrically connected to a control terminal of the switch control unit and the control terminals of the plurality of row control switches, and the plurality of column control electrodes are electrically connected to the control terminal of the switch control unit and the control terminals of the plurality of column control switches.

20. A display device, comprising a display module, wherein the display module comprises a bracket structure, an adhesion-reducing adhesive structure, a plurality of display panels and a plurality of back plates, wherein
the plurality of back plates are disposed on a non-light-emission side of the plurality of display panels; and
the bracket structure is disposed on a side of the plurality of back plates facing away from the plurality of display panels through the adhesion-reducing adhesive structure, and adhesion of the adhesion-reducing adhesive structure is variable.
